(19) United States
(12) Patent Application Publication
(10) Pub. No.: US 2013/0181246 A1
(43) Pub. Date: Jul. 18, 2013

(54) ILLUMINATING DEVICE WITH LED SURFACE LIGHT SOURCE COVERED WITH OPTICAL FILM

(71) Applicant: Hangzhou New Sun Energy Technology Co.,Ltd., Hangzhou (CN)

(72) Inventor: Mingfan Wu, Hangzhou (CN)

(73) Assignee: Hangzhou New Sun Energy Technology Co., Ltd., Hangzhou (CN)

(21) Appl. No.: 13/784,218

(22) Filed: Mar. 4, 2013

Related U.S. Application Data
(63) Continuation of application No. PCT/CN2011/071182, filed on Feb. 23, 2011.

(30) Foreign Application Priority Data
Sep. 2, 2010 (CN) 201010271534.X

(51) Int. Cl. H01L 33/58

(52) U.S. Cl. CPC H01L 33/58
USPC 257/98; 438/27

(57) ABSTRACT

The present invention provides an LED light source, and particularly provides an illuminating device with an LED surface light source covered with an optical film. The device includes: an LED point light source, an illuminator, and a heat sink; wherein the illuminator is an optically transparent solid geometry with an optical film covering the outer surface thereof; wherein at least one outer surface of the solid geometry is an incident surface and at least one outer surface of the solid geometry is an emergence surface; and the optical film is a solid optical medium film; and the LED point light source is fixed on the heat sink, matching with the incident surface of the illuminator.

### CROSS-REFERENCE TO RELATED APPLICATIONS

This application is a continuation of International Patent Application No. PCT/CN2011/071182, with an international filing date of Feb. 23, 2011, designating the United States, now pending, which is based on Chinese Patent Application No. 201010271534.X, filed Sep. 2, 2010. The contents of these specifications are incorporated herein by reference.

### BACKGROUND OF THE INVENTION

1. Field of the Invention

The present invention relates to an LED light source, and in particular, to an illuminating device with an LED surface light source covered with an optical film, which is widely applied in the fields related to the LED surface light source such as display, lighting, environmental protection, medical healthcare, backlight source.

2. Description of the Related Art

Direct glare produced by the LED as an illuminator of the point light source is a serious source of light pollution. To overcome direct glare produced by the point light source illuminator, various technical solutions of the LED surface light source have been gradually introduced to the lighting field, such as a direct-entry LED surface light source produced by adding diffusing agent and a surface light source produced by using the light guide panel technique (for example, mechanical engraving, printing dot, laser engraving, special structure of the light guide panel). The surface light source proposed by the author in the patent “HIGH LUMINANCE SURFACE LIGHT SOURCE (Patent Authorization No. 200620101666.7) is also a simple technical solution thereof.

As disclosed by the Chinese invention patent No. CN100508222C, the existing LED-based surface light source devices have still a quite low energy utilization rate. In one aspect, the fabrication technology of the LED is still under constant improvement and the wall-plug efficiency has still a lot of headroom for further improvement. Moreover, the secondary encapsulation efficiency (secondary efficiency for short) of the LED as a practical device of the surface light source is still quite low, which is an important cause to the low efficiency of the light guide panel. The light guide panel's efficiency is defined as the percentage of total effective luminous flux emitted from the main emergence surface of the light guide panel in the total luminous flux coupled into the light guide panel. According to the data revealed by the technical document TP29 published by Lumileds Lighting in the US, the highest secondary efficiency of its large-power LED-based surface light source is 50% and the efficiency of the light guide panel is about 60%.

The light guide efficiency depends mainly on the overall structure of the light guide panel and the scattering principle and the structure of a scattering mechanism layer. The efficiency of a traditional light guide panel mentioned in the American U.S. Pat. No. 5,396,350 is only 10%-20%. This and U.S. Pat. No. 5,461,547, U.S. Pat. No. 5,359,691, and U.S. Pat. No. 5,854,872 proposed different light guide panels and structures of scattering mechanism layer and made improvements on the directivity of emergent light from and the efficiency of the light guide panel. Anyhow, according to the article “Highly-efficient Backlight for Liquid Crystal Display Having no Optical Films” in Volume 83 of an academic journal Applied Physics Letters, the existing efficiency of light guide panel can only reach 60% and the scattering mechanism layer has an array of reflective microprism. This type of light guide panel has less ineffective light emergence and better control on angle of effective emergence. However, there still exist such problems as low efficiency of light guide, manufacturing difficulty and high cost. Existing light guide panels designed for primary light source have a certain type of scattering mechanism layer arranged on the main surface of the light guide panel opposite to the main emergence surface, and the incident light changes the original path of reflection when reaching to the scattering unit and emerges from the main emergence surface. Although the light guide efficiency can be maximized by optimizing the design of scattering mechanism layer and scattering unit, light will emerge unavoidably from the main surface opposite to the main emergence surface and become ineffective emergent light. Therefore, the light guide efficiency has a theoretical ceiling and cannot be higher. Existing LED-based surface light source, like the surface light source structure revealed by the Chinese invention patent No.: 03101472.0 and Chinese utility model patent 01267387.0, adopts similar principles, and is therefore difficult to break through the ceiling of theoretical efficiency of the light guide.

The surface light source structure revealed by the Chinese invention patent CN100508222C has still such problems as complicated manufacture process, high cost, single functionality and low performance/price ratio and cannot be extensively applied to display, lighting, environmental protection, medical healthcare, backlight source and other technical fields related with LED light source.

### SUMMARY OF THE INVENTION

The present invention is implemented by using the following technical solutions:

An illuminating device with an LED surface light source covered with an optical film and a manufacture method for the same, wherein the device includes an LED point light source 1, an illuminator 2, and a heat sink 3.

The illuminator 2 is an optically transparent solid geometry 4 with an optical film covering the outer surface thereof; the solid geometry 4 is a solid object with its space filled by solid matters (P.10 in “Three Dimensional Structure” Version 1, August 2002, Authors: Xu Chao and Huang Dan).

At least one outer surface of the solid geometry 4 is an incident surface 5 and at least one outer face of the solid geometry is an emergence surface 6. The incident surface 5 refers to the outer surface by which the light from the illuminator of the LED point light source 1 reaches inside the solid geometry 4. The emergence surface 6 refers to an outer surface from which the light of the illuminator 2 is emitted from the solid geometry 4.

The outer surface of the solid geometry 4 of the solid geometry the illuminator 2 is provided with at least one optical dielectric film made of submicron particles or nano particles, where the thickness of the film is from 91 nm to 5 mm.

The LED point light source 1 is fixed on the heat sink 3, matching with the incident surface 5 of the illuminator 2.

The optical film refers to a solid optical dielectric thick film or a functional optical dielectric thin film. All optical films have optical loss, which reduces the luminous efficiency and display performance of the emergence surface 6. To reduce the optical loss of the optical layer, especially the absorptive loss of light, it is possible to manufacture optical film with little absorptivity based on known technologies for application on optical components, for example, the test result of optical thin-film absorptivity revealed by the Journal of Zhejiang University (Natural Science) P536 (July 1989, 4th, Volume 23 “Testing the Absorptivity of Optical Film with Optical-thermal Deflection Spectrum and its Calibration”, Chen Wenbin, Shi Boxuan and Huang Xuebo).

| Monolayer Film | | Multilayer Film | |
|---|---|---|---|
| Material | Absorptivity | File Series | Absorptivity |
| ZnS | 3.4 × 10⁻⁵ | G(HL)²(LH)²2LHIA | 3.6 × 10⁻³ |
| MgF₂ | 2.7 × 10⁻⁴ | ZnS/MgF₂ | |
| ZrO | 9.3 × 10⁻⁵ | ZnS—MgF₂ five-layer Si | 4.6 × 10⁻⁶ |
| H_{f}O mixed | 9.1 × 10⁻⁵ | optical battery filter | 1.2 × 10⁻⁸ |
| material | | ZnS—MgF₂ 1.6 μm laser | |
| | | polarizer | |
| Ta₂O₅ mixed | 7.9 × 10⁻⁴ | G\|HLH₄(ML)2H₄LH\|A | 5.1 × 10⁻⁴ |
| material | 2 × 10⁻⁵ | ZrO₂/SiO₂ | |
| SiO₂ | | | |

Especially, based on the data of dielectric optical film material revealed in P356 of “Glass Plating” (Science Publishing House, Version 1, May 1988 (Liechtenstein) H. K. Author: Purker Translated by: Zhong Yongan, Xie Yushen and Wu Yusi), the basic feature of dielectric optical film is that the absorptivity is quite low (α<10³ cm⁻¹) within relevant spectrum region. Hence, the present invention chooses the optical film made of dielectric optical materials, with quite low absorptivity α<10³ cm⁻¹ for visible light, can meet basically the requirements of various LED surface light source. There are detailed introduction about materials and manufacture technologies of optical dielectric film in university textbooks “Thin Film Technologies” (1st version in October 1991, Authors: Wang Liheng, Huang Yuntian and Zheng Haitao, Tsinghua University Publishing House), “Optical Thin Film” (Published in 1976, written by Writing Group of “Thin Optical Film”, Shanghai People's Publishing House), “Optical Thin Film Technologies” (version 1 in October 2005, Authors: Lu Jinjun and Liu Weiguo, Northwest Industry Publishing House), “New Electronic Thin Film Technologies” (version 1, September 2002, Authors: Chen Guanghua, Deng Jinxiang et al., Chemical Industry Publishing House), “Manual of Thin Film Science and Technologies” (version 1 in March 1991, Tsinghua University, Tian Minbo; Shenyang Vacuum Technology Research Institute, Edited and Translated by Liu Deling, Mechanical Industry Publishing House) and will not be detailed any further. One objective of the present invention is to apply the dielectric optical film directly onto the outer surface of the emitter 2 of the LED area light surface illuminator to produce a functional thin layer of optical dielectrics. Another objective is to invent a method of diffusing optical dielectric film materials into the polymer of parent substance of transparent epoxy resin or transparent silicon resin according to weight percents, apply it onto the outer surface of the illuminator 2 of the LED surface light source illuminator and then produce a thick film of solid optical dielectrics on the outer surface of the illuminator 2 through curing.

The LED point light source 1 is fixed onto the heat sink 3 and arranged on the incident surface 5 of the illuminator 2.

Along with the development of LED technologies, the LED point light source 1 can be a prefabricated LED point light source like SMD chip or prefabricated module of LED line light source, which are welded onto the printed circuit board and then fixed onto the heat sink, and be arranged onto the incident surface of the illuminator's solid geometry. To reduce thermal resistance and lumens depreciation, the optimum method is to integrate and bind an LED chip directly onto the LED line light source or expansive light source on the heat sink 3. For illumination by white light, LED point light source can use blue light chip to stimulate the yellow fluorescent powder, or use R, G and B chips for light mixture to produce white light.

The core of the present invention is using the illuminator 2 to replace the traditional light guide panel. Hence, it needs to describe in details the manufacture of the illuminator 2.

At the outer surface of the solid geometry 4 in the illuminator 2, different positions of the LED point light source 1 in the illuminator and different principles for light emergence from emergence surface of the illuminator 2 will implement different functions. As shown in FIG. 2, the outer surface of the solid geometry 4 is divided into the incident surface 5, the emergence surface 6 and the reflection surface 7 based on the function. The reflection surface refers to the outer surface by which the solid geometry 4 reflects internal light of the illuminator 2 back inside of the illuminator 2.

During the fabrication for the present invention, different outer surfaces of the solid geometry 4 must be covered with different optical films. Since the LED point light source 1 is configured to different positions, the emergence surface 6 must be covered with different optical films. Based on the industrial practice of adopting two backlight solutions (side-entry and direct-entry) based on different positions of the incident light of backlight source, side-entry and direct-entry illuminators are employed for different positions of the LED point light source 1 in the illuminator 2. As shown in FIG. 1, the solid geometry 4 is an illuminator made of organic glass plate and the geometry is a solid polyhedron-hexahedron and has totally six surfaces. If LED point light source illuminator is arranged on one side surface of the hexahedron, this side surface is the incident surface 5 (it is the reflection surface if no LED point light source is arranged here. Hence, the Fig. has only two incident surfaces and other two sides are reflection surfaces). Two parallel outer surfaces of the hexahedron are emergence surfaces 6 (one parallel outer surface is taken as the emergence surface and the other outer surface is taken as the reflection surface). The illuminator 2 is a side-entry illuminator, which refers to that the incident light transmits through full reflection and light emerges from the emergence surface by undermining the full reflection conditions. The illuminator as shown in FIG. 2 is a side-entry illuminator in which the light enters form the side, transmits through full reflection, and comes out by undermining the full reflection conditions through the geometry's parallel surfaces. The emergence surface 6 is called the emergence surface of the side-entry illuminator.

As shown in FIG. 3, the solid geometry 4 is an illuminator made of organic glass plates and the geometry is a solid polyhedron-hexahedron and has totally six surfaces. If the LED point light source illuminator is arranged on one parallel surface of the hexahedron, this parallel surface is the incident surface 5 and the other parallel surface is the emergence surface 6 (other side surfaces are reflection surfaces 7). The illuminator 2 is a direct-entry illuminator, which refers to that the incident light transmits along a straight line and emerges the scattered light deviating from the direction of incident light. The illuminator as shown in FIG. 4 is a direct-entry illuminator in which the light enters along a straight line of one parallel surface of the geometry and emerges the scattered light from another parallel surface of the geometry, and the emergence surface 6 is called the emergence surface of the direct-entry illuminator.

Another objective of the invention is to apply matching optical film onto the outer surface of the solid geometry 4 with different optical functions by known applying method to make possible LED surface light source with higher efficiency and more functions.

(1) The incident surface 5 of the invention allows the entry of effective light of the illuminator into the solid geometry 4 and most light can enter the solid geometry 4 by common light coupling method. Based on the light transmission principles, the incident surface 5 has still reflective loss of light. Therefore, the optical film might not be applied when the incident surface 5 occupies a small percentage in the outer surface of solid geometry 4. However, when the reflective loss at the incident surface 5 affects the illumination efficiency and display performance of emergence surface 6, the optical film shall be applied to improve the utilization of incident light for the illuminator of the LED point light source 1, increase the transmitted light and reduce the reflective loss on the incident surface 5. Optical films with such performance can be fabricated using known technologies, such as the antireflective coating and antireflective film commonly used in optical devices. As shown in FIG. 21 and as revealed at P111 by the university textbook “Thin Film Technologies” (1st version, October 1991, Authors: Wang Liheng, Huang Yuntian and Zheng Haitao, Tsinghua University Publishing House): Fraunhofer used the acid etching method to produce optical antireflective film as early as in 1817 The simplest antireflective coating is to apply a thin film having low-refractivity on the glass surface. As revealed on page 122: the following conclusion can be reached from the above discussion:

(2) When n₁d is λ/4, the reflectivity R has a limit value, and

R=((n₀n₂−n₁²)/(n₀n₂+n₁²))²

When n₀<n₁<n₂, R is the minimum value. When n₀<n₁>n₂, R is the maximum value. That is, coating a low-refractivity λ/4 film can reduce R to achieve the objective of increasing the transmission intensity. Hence, it is called antireflective film.

(3) As for the normal incidence of ray into the monolayer λ/4 optical film from air, the refractivity n₁ of film material is the only factor to control R. The bigger n₁ is, the bigger R is; the smaller n₁ is, the smaller R is. n₁=n₂ is a borderline between antireflective and reflection-enhancing. When n₁<n₂, the film is antireflective. As revealed on page 124, for a thin film with an optical thickness of λ/4, if n₁=(n₀n₂)^{1/2}, the reflectivity can be reduced to zero . . . . If it is applied to glass with a refractivity of 1.65, the surface reflectivity of central wavelength can be reduced from 6% to 0.5%. According to the introduction on page 125, as to substrate with a refractivity of 1.52, deposit firstly a thin film of silicon monoxide with a refractivity of 1.70 and thickness of λ₀/4. In this case, n₁=n₂²/n₃=1.90 which is equivalent to that the substrate's refractivity increases from 1.52 to 1.90. Additional application of magnesium fluoride film n₁=1.38 can just meet the ideal condition of antireflective and the incident light with a wavelength of λ₀ can be reduced to almost zero and almost 100% light passes through the glass. If it needs to eliminate reflection within a wide scope or preset multiple wavelengths, a wideband antireflective film needs to be prepared. The optical thickness of common three-layer antireflective film is λ₀/4−λ₀/2−λ₀/4. n₁ and n₃ are normally selected to meet n₃²=n₁²n₄ and n₂ can suitably selected based on relevant conditions.

It is known from above well-known technologies that the reflective loss may approach zero theoretically and may be eliminated within a wide range or preset multiple wavelengths. To eliminate the reflective loss of light wave λ, the optical thickness of film must be odd times of λ/4 (University textbook “Thin Film Technologies” 1st version, October 1991, Authors: Wang Liheng, Huang Yuntian and Zheng Haitao, Tsinghua University Publishing House).

It is also known through published data that human eyes are the most sensitive to the yellow-green light with a wavelength of λ=555 nm under bright conditions; or to the light with a wavelength of λ=507 nm under dark conditions “Color TV Illumination Principle and Lighting Skills”, Beijing Agricultural University Publishing House, version 1, September 1998, Authors: Shi Kexiao and Yu Baofu).

The present invention is directed to eliminating the reflective loss of light wavelength λ, which is the most sensitive to the vision of human eyes. When the outer surface of the solid geometry 4 is taken as the incident surface, it shall be covered with an optical film 8 whose refractivity is smaller than that of solid geometry; and the film's optical thickness is controlled to an odd multiple of 126 nm to an odd multiple of 139 nm, which will reduce the loss of optical wave most sensitive to the vision of human eyes at the incident surface and most effective incident light from LED point light source enters into the illuminator through optical coupling. This increases the utilization of LED point light source, which will be quite important when the incident surface is quite big.

The present invention chooses further wideband antireflective film as the covering film with a low refractivity 8. The wideband antireflective film refers to a multilayer antireflective film. For example, choose the three-layer antireflective film MgF₂ (n₁=1.38), ZrO₂ (n₂=2.1) and CeF₃ (n₃=1.62). The optical thickness of film is λ/4−λ/2−λ/4 (λ is from 507 nm to 555 nm), namely, a three-layer wideband antireflective film with an optical thickness of 126.75 nm to 138.75 nm, 253.5 nm to 277.5 nm, or 126.75 nm to 138.75 nm. In view of the production cost, the film's optical thickness can be controlled respectively to three-layer wideband antireflective film (126 nm to 139 nm, 253 nm to 277 nm and 126 nm to 13 9 nm). This reduces the reflective loss of optical wave most sensitive to the vision of human eyes within the entire range of visible light at the incident surface.

2). The reflection surface 7, among the outer surfaces of the solid geometry 4 in the invention, mainly reflects ineffective emergent light inside the illuminator into the solid geometry 4 based on the principle of optical reflection, which emerges for the second time from the emergence surface. It achieves better control on the angle of effective emergent light, more uniform emergence and higher luminous intensity at the emergence surface. This type of optical film can be completely implemented based on known technologies and the reflection efficiency can reach 100% theoretically.

Based on the data published in P116 of “Optical Thin Film” (written by the Writing Group of “Optical Thin Film”, Shanghai People's Publishing House, published in 1976):

TABLE 4.3
Reflectivity of ZrO₂ + SiO₂ multilayer Reflection
film n_{H} = 1.90 n_{L} = 1.46

| | Layer | | | | | | | |
|---|---|---|---|---|---|---|---|---|
| | 1 | 2 | 3 | 4 | 5 | 6 | 7 | 8 |
| R | 16.6 | 19.5 | 36.5 | 38.8 | 55.8 | 57.5 | 70.0 | 72.3 |
| | Layer | | | | | | | |
| | 9 | 10 | 11 | 12 | 13 | 14 | 15 | 16 |
| R | 81.7 | 82.6 | 88.7 | 89.3 | 93.2 | 93.5 | 95.3 | 96.3 |

| | Layer | | | | | | | | |
|---|---|---|---|---|---|---|---|---|---|
| | 17 | 18 | 19 | 20 | 21 | 22 | 23 | 24 | 25 |
| R | 97.6 | 97.8 | 98.6 | 98.7 | 99.2 | 99.3 | 99.5 | 99.6 | 99.7 |

In principle, this film can obtain a reflectivity approaching 100% for a certain wavelength.

According to the study result published on page 24 of “Optical Thin Film Technologies” (Northwest Industry University Publishing House, October 2005, 1st version, Authors: Lu Jinjun and Liu Weiguo)): it is already known from discussion of monolayer film's property that the reflectivity will increase when the substrate with a refractivity of n_{G} is applied with a film with an optical thickness of λ₀/4 and high refractivity of n₁.

As shown in FIG. 21 and revealed on page 122 of the University Textbook “Thin Film Technologies” (1st version in October 1991, Authors: Wang Liheng, Huang Yuntian and Zheng Haitao, Tsinghua University Publishing House); the following conclusion can be inferred accordingly:

(1) Coating monolayer film on an optical component can change its reflectivity. When the light beam makes a normal incidence and the film's optical thickness is n₁d=λ/4 (or an odd multiple of λ/4), the reflectivity R experiences the biggest change along with the film's refractivity. When the optical thickness is n₁d=λ/2 (or an odd multiple of λ/4), the reflectivity R keeps unchanged. Applying λ/4 film with a high refractivity can increase R and achieve the objective of improving reflective intensity. This type of film is called reflection-enhancing film.

The present invention adopts a reflection film 12, which is ZrO₂+SiO₂ multilayer reflection film series and the optical thickness of each layer is respectively an odd multiple of 126 nm to an odd multiple of 139 nm.

The present invention preferably selects λ/4 (λ is 507 nm-555 nm), i.e., (507 nm-555 nm)/4, (126.75 nm-138.75 nm) as the optical thickness of each layer in a multilayer dielectric film with alternate use of high and low refraction. In view of the production cost, the film's optical thickness can be controlled respectively to 126 nm and 139 nm. This is because that light beams reflected from all interfaces of the film have the same phase when reaching the previous surface, which results in constructive interference. This type of dielectric film series can obtain a higher reflectivity, approaching hopefully a theoretical reflectivity of 100%. Particularly, the reflectivity of the light wave most sensitive to the vision of human eyes at the reflection surface is increased. (“Optical Thin Film Technologies”, Northwest Industry University Publishing House, version 1, October 2005, Authors: Lu Jinjun and Liu Weiguo, P.24).

At present, glass bead reflection film is commonly used. To render more uniform emergence of light and based on the principle revealed in “Microprism Reflection film and its Application Prospectus” (Road Traffic Science and Technology, Volume 1 in March 1998, Wang Zhihe, Wang Peixin and Shan Mingzheng (Beijing Aviation Material Research Institute), the reflection film can use the prism reflection film to control the angle of emergent line and achieve more uniform emergence.

If the reflection film is not imposed with high requirements during implementation of the present invention, we can embed directly the prefabricated reflection film with a reflectivity greater than 90% into the reflection surface of the solid geometry or adhere it unto the reflection surface.

(3) As to the emergence surface of the side-entry illuminator in the present invention, it is known through the optical principle and the light path in FIG. 23 that the side-entry illuminator transmits light based on the full-reflection principle. It is known through the full-reflection theory that when the light is refracted from the dielectric layer with a high refractivity to that with a low refractivity (such as from PMMA materials to air), the refracted light is emitted with an angle more oblique than the incident light. When the incident angle is greater than a certain angle, light cannot refract into air, but will have complete inward reflection at the emergence surface. The light of the LED point light source 1 transmits directly into the illuminator through the full optical coupling at the incident surface. The transmitted energy is only slightly consumed in this process, and the light energy can be transmitted effectively based on the full reflection theory. PMMA has a transmission rate of 92%, low haziness and low optical absorptivity. The light can transmit along the material for a long distance with small attenuation. However, light cannot be led out from the emergence surface. On one hand, the side-entry illuminator transmits light based on the full reflection theory. On the other hand, the illuminator's emergence surface is required to adopt an opposite theory, i.e., undermining the conditions of full reflection, interfering with the full-reflection optical elements of light and changing the path of light so that the light can be led out from the emergence surface and form bright and uniform surface light source. At present, optical film has not been extensively adopted yet.

The illuminator in the present invention takes the outer surface of the solid geometry 4 as the emergence surface of side incidence by experimentation of the simplest method. The covering film has a refractivity higher than that of solid geometry, a transmission rate greater than 90%, and an optical thickness which is an odd multiple of (507 nm-555 nm)/4. Namely, the film 9 of high refractivity, which is an odd multiple of (507 nm-555 nm)/4=(126.75 nm-138.75 nm), undermines the condition of full reflection, interferes the light's full reflection optical elements and changes the path of light (“Optical Thin Film”, written by the Writing Group of “Optical Thin Film”, Shanghai People's Publishing House, published in 1976, P.5). As result, the light comes out from the emergence surface and the luminous intensity at the emergence surface is increased. Particularly, it has increased the luminous intensity of the light wave most sensitive to the vision of human eyes at the emergence surface.

Through the optimization by multiple experiments, the present invention chooses a refractivity greater than that of the solid geometry, an optical thickness of film which is an odd multiple of 126 nm or an odd multiple of 139 nm and functional optical dielectric thin film with a transmission rate greater than 90%; or containing particles with a specific area greater than 50 to 250 (m²/g) and the average particle size of 5 nm to 15 nm. In view of the production cost, the optical thickness of film can be respectively controlled to odd times of 126 nm to 139 nm, and the optical film of nano titanium dioxide with a transmission rate greater than 90% is used, or by diffusing nano titanium dioxide with an average particle size of 5 nm to 15 nm and specific area greater than 50 m²/g to 250 m²/g into the polymer optical solid dielectric thick film formed by parent substance of optically transparent epoxy resin or optically transparent silicon resin according to a weight percent of 0.1% to 5%. The film has a thickness of 0.01 mm to 1 mm and transmission rate is greater than 90% and covers the solid geometry as the film 9 with a high refractivity. It is tested that the film has a refractivity above 1.8. The transmission rate of the emergence surface is greater than 90% and the luminous intensity is greatly improved.

(4) The emergence surface of said direct-entry illuminator in the present invention is totally different from the emergence surface of the side-entry illuminator. It is known from the light path in FIG. 22 that the emergence surface 6 of the direct-entry illuminator transmits light by means of direct transmission. Direct transmission of the point light source illuminator will definitely cause optical pollution of direct glaring. Hence, the emergence surface 6 of the direct-entry illuminator shall diffuse the transmitted light and takes the scattered light deviating from the direction of incident light as the emergent light, which overcomes the optical pollution caused by direct glaring.

The diffusion film is also called scattering film and has been applied in backlight source. The optical diffusion film revealed by the invention patent (Specification Publication No.: CN1453359A) is a type of such films.

The present invention determines the outer surface of the solid geometry 4 as the direct emergence surface through experiment. The simplest method is to add optical diffusing agent (such as powder of high-purity silicon dioxide, and light-weight barium sulfate) with a refractivity higher than the epoxy resin or silicon resin and the particle size greater than the wavelength of visible light (0.38 μm to 0.78 μm) into the epoxy resin and other transparent resin. It can be suitably controlled in accordance with thickness and requirements of products that, the optical diffusing agent can be diffused into parent substance of the transparent epoxy resin or transparent silicon resin according to a weight percent of 1% to 5% to form a polymer. After mixing and blending, the polymer is applied onto the emergence surface of the solid geometry for curing to form a diffusion film 10 with a thickness of 1 mm to 3 mm. While increasing the light diffusion and covering the light source and glaring light source, the entire emergence surface emits gentler light to achieve the comfortable effect of light-transmitting but not transparent. It is tested that the film thickness is greater than 80%, diffusion rate is greater than 0.6 and transmission rate is greater than 80%, which meets basically the requirements of LED surface light source.

To further improve the optical property of surface light source, particles with special wavelength, like fluorescent powder, are added to the optical film in order to improve the optical and physical property of the surface light source. In experiments, the emergence surface of direct-entry illuminator in the solid geometry 4 is the thick polymer film formed by diffusing fluorescent powder (the central particle size D50 is from 8 μm to 20 μm) into parent substance of the optically transparent epoxy resin or the optically transparent silicon resin according to a weight percent of 5% to 30% and the film thickness is 0.1 mm to 3 mm. It is tested that the white light temperature at the emergence surface of the film can be controlled and the color rendering index can exceed 90, which expand further the optical and physical property of the surface light source.

(5) To further expand the function of LED surface light source illuminator, when the LED point light source 1 in LED surface light source illuminator has an LED chip containing wavelength 365 nm to 410 nm, the emergence surface of the solid geometry 4 is covered with the optical catalyst film 11 to fabricate the optical catalyst assembly. LED surface light source is an extremely good optical catalyst lighting device.

Based on the open knowledge on pages 103 to 105 of “Lighting Manual” (Science Publishing House, version 1, July 2005 [Japan] Lighting Society, Translators: Li Nong and Yang Yan), the study on photocatalyst started from two decades ago and its direction has changed for several times. When the light strikes on TiO₂ and the makes use of the powerful oxygenolysis ability of photocatalyst, it can kill bacteria, prevent dust, remove unpleasant odor and purify the environment. To make the material surface has the self-cleaning function of TiO₂, TiO₂ film or paint containing diffused TiO₂ powder and solution of Titanium organic compounds can be applied to the glass surface.

Through experiments, the present invention adopts an optical film of nano titanium dioxide with a specific area (for the outer surface) greater than 140 m²/g and an average particle size in the range of 5 nm to 15 nm for the photocatalyst film 11 at the outer surface of the solid geometry 4, and the film's optical thickness is an odd multiple of 91.25 nm to an odd multiple of 102.5 nm. In this case, the LED chip with a wavelength of 365 nm to 410 nm of the LED point light source in the illuminating device with an LED surface light source achieves the desired effect.

Through experiments and optimization, the present invention finds that when the LED point light source 1 contains an LED chip with a wavelength of 365 nm to 410 nm, the photocatalyst film 11 on the emergence surface of the solid geometry 4 is a thick polymer film formed by diffusing nano titanium dioxide with an average particle size of 5 nm to 25 nm and specific surface area greater than 140 m²/g into parent substance of the epoxy resin or silicon resin=according to a weight percent of 0.1% to 10%, and the film thickness is from 0.1 mm to 3 mm.

It is tested that, as for the illuminator covered with a photocatalyst optical film, hardness after drying is greater than and equal to 5H and the following cleaning effects are achieved: the concentration of toluene is decreased by 80%, ammonia's degradation rate is greater than and equal to 80%, formaldehyde's degradation rate is greater than and equal to 80%, hydrogen sulfide is greater than and equal to 90% and sterilization rate is greater than and equal to 98%. Therefore, this embodiment illustrates an extremely good photocatalyst component, which can purify air and sterilize and is an extremely good environment-friendly illuminator.

In summary of above analysis, the outer surface of the solid geometry 4 is covered with different optical films, which provides a feasible method to improve the luminous intensity and color rendering property of LED surface light source and expand the function of LED surface light source.

Along with the improvement of electronic thin film technology and the detecting and preparation means and greater variety of new thin film materials in recent years, the research comes from macroscopic micron dimension to nano dimension between the macroscopic and microscopic (atoms and molecules). When substance particles are in the dimension from several to tens of nanometers, their structure and property are different from both single atoms and molecules and lump substances comprised of lots of atoms or molecules, and obtain many new physical effects. Since nano particles are equivalent or smaller than the wavelength of light wave and other physical features, the periodic boundary conditions are undermined and the light feature will demonstrate new small-dimension effect. As the quantitative ratio of atoms between the outer surface and body of nano particles increases, the effect at the outer surface and interface shall be improved remarkably. Particularly, the structure of energy band will change when the size of particles drops to extremely small, which results the so-called quantum size effect. The present invention proves through experiments the choice of optical films containing 0.1% to 10% submicron or nanometer compound particles. The light characteristics at a wavelength of 507 nm to 555 nm demonstrate new physical effects, which basically meet the requirements of different LED surface light sources.

Along with the rapid development of electronic thin film technologies, there are more methods for production of thin films. The optical film in this device can be produced by known methods commonly used, such as physical vapor deposition, chemical vapor deposition, collosol-gelatin, injection and splattering. (“Thin Film Science and Technology Manual”, Mechanical Industry Publishing House, March 1991, First Version, Tsinghua University, Tian Qingbo; Shenyang Vacuum Technology Research Institute, Edited and translated by Liu Deling).

The material and shape of solid geometry for the illuminator in this device are chosen based on the optical principle and light distribution curve of lighting devices. It generally adopts optical plastic such as PMMA, PC, PS, SAN, CR-39, TPX and PET, optical glass and optical ceramics. The geometry is a solid polyhedron, solid rotating body or solid geometry comprised of solid polyhedron and solid rotating body, like shapes of plate, tube, bar and curved plate.

Beneficial effects: The present invention proposes an LED surface light source device covered with an optical film, that features convenient implementation and great improvement of luminance and color rendering property, simple manufacture process, low cost, high performance/price ratio and with various functions of environmental protection, sterilization, medical healthcare, prevention of static electricity as well as its preparation method.

### BRIEF DESCRIPTION OF THE DRAWINGS

FIG. 1 is a schematic structural diagram of a glaring-free LED plane light source according to a first embodiment of the present invention;

FIG. 2 is a longitudinal section of the side-entry illuminator covered with a film of high refractivity according to the first embodiment of the present invention;

FIG. 3 is a schematic structural diagram of a multi-functional LED plane light source according to a second embodiment of the present invention;

FIG. 4 is a longitudinal section of the direct-entry illuminator covered with a diffusion film according to the second embodiment of the present invention;

FIG. 5 is a longitudinal section of the direct-entry illuminator covered with the fluorescent powder diffusion film according to the second embodiment of the present invention;

FIG. 6 is a longitudinal section of the direct-entry illuminator covered with the photocatalyst film according to the second embodiment of the present invention;

FIG. 7 is a schematic structural diagram of a tubular LED surface light source according to a third embodiment of the present invention;

FIG. 8 is a longitudinal section of a side-entry illuminator according to the third embodiment of the present invention;

FIG. 9 is a schematic structural diagram of an LED curved surface light source according to a fourth embodiment of the present invention;

FIG. 10 is a lateral section of the side-entry illuminator for according to the fourth embodiment of the present invention;

FIG. 11 is a schematic structural diagram of a multifunctional LED columnar surface light source according to a fifth embodiment of the present invention;

FIG. 12 is a longitudinal section of the side-entry illuminator covered with the reflection film according to the fifth embodiment of the present invention;

FIG. 13 is a longitudinal section of the side-entry illuminator covered with a diffusion film according to the fifth embodiment of the present invention;

FIG. 14 is a longitudinal section of the side-entry illuminator covered with photocatalyst film according to the fifth embodiment of the present invention;

FIG. 15 is a structural diagram of an LED polyhedron surface light source according to a sixth embodiment of the present invention;

FIG. 16 is a schematic structural diagram of an LED unconventional surface light source illuminator according to a seventh embodiment of the present invention;

FIG. 17 is a schematic structural diagram of an LED point light source for according to the seventh embodiment of the present invention;

FIG. 18 is a schematic structural diagram of an LED surface light source fluorescent lamp according to an eighth embodiment of the present invention;

FIG. 19 is a longitudinal section of an LED surface light source fluorescent lamp illuminator according to the eighth embodiment of the present invention;

FIG. 20 is a schematic structural diagram of an LED photocatalyst spherical lamp for according to a ninth embodiment of the present invention;

FIG. 21 is an optical path analysis diagram of an antireflective film;

FIG. 22 is an optical path analysis diagram of a low-refractivity film 8 according to the present invention; and

FIG. 23 is an optical path analysis diagram of a high-refractivity film 9 according to the present invention.

Reference signals and denotations thereof:
1. LED point light source
2. Illuminator
3. Heat sink
4. Solid geometry
5. Incident surface
6. Exist surface
7. Reflection surface
8. Low-refractivity film
9. High-refractivity film
10. Diffusion film
11. Photocatalyst film
12. Reflection film

### DETAILED DESCRIPTION OF THE INVENTION

### Embodiment 1

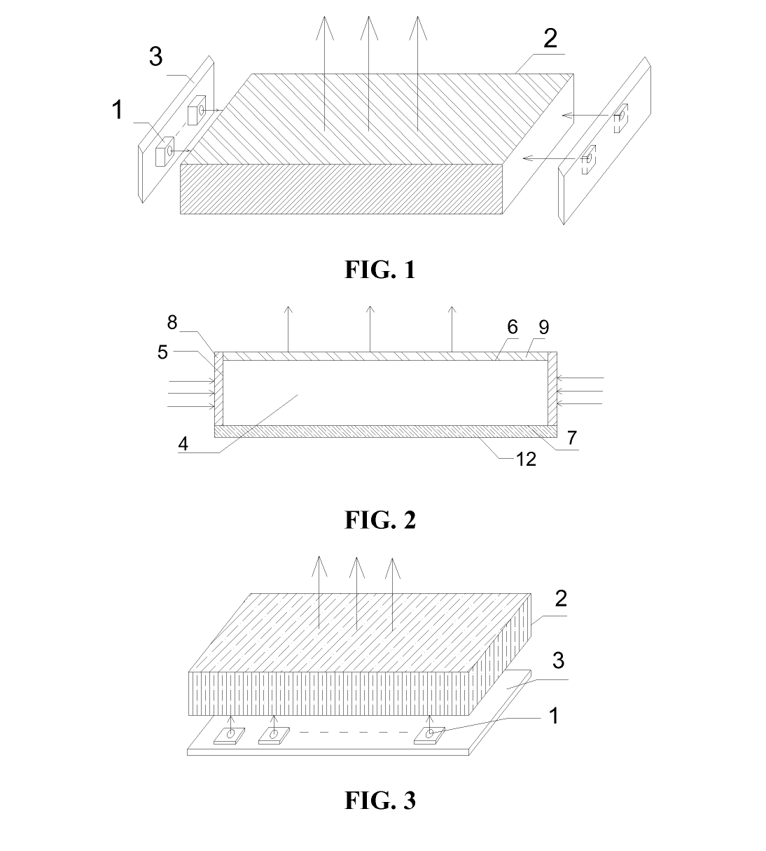

A glaring-free LED plane light source is provided. As shown in FIG. 1, an LED point light source 1 uses 90 3528SMD LEDs, which are welded to a 165 mm(L)×10 mm(W) aluminum-based printed circuit board. The LEDs are firstly fixed onto a heat sink 3 and then arranged on the incident surface of an illuminator 2. A solid geometry 4 of the illuminator 2 is a PMMA plate with a dimension of 160 mm(L)×65 mm(W)×6 mm(D). The geometry is a solid polygon-hexahedron made of PMMA materials and has totally six surfaces. The LED point light source 1 is arranged on two opposite sides of the hexahedron, and the illuminating side is an incident surface 5. Hence, the figure illustrates two incident surfaces and other two side surfaces are reflection surfaces. One parallel outer surface of the hexahedron is an emergence surface 6 and another parallel outer surface is a reflection surface 7. The illuminator is a side-entry illuminator with light incidence from one side surface and light emergence from one parallel surface of the geometry. The emergence surface needs to be covered with a high-refractivity film 9. As shown in FIG. 2, since the refractivity of PMMA material n=1491, nano materials with a refractivity n greater than 1491 is selected. After several experiments, the present invention selects nano powder of titanium dioxide with an average particle size of 5 nm and a specific area (for outer surface) of 50 to 250 (m²/g), which is diffused uniformly in a polymer of optically transparent epoxy resin or optically transparent silicon resin according to a weight percent of 0.4%, applied onto the emergence surface 6 of solid geometry by using the collosol-gelatin method, solidified below 60° C. to form a solid optical dielectric thick layer (with a thickness of 0.05 mm) at the emergence surface 6 as the high-refractivity film 9. During application, other outer surfaces of the solid geometry 4 must be covered. Similarly, when the incident surface is applied with a low-refractivity film 8 by using a well-known method and the reflection surface is applied with a reflection film 12, other outer surfaces of the solid geometry must be covered to fabricate a qualified illuminator.

The LED surface light source illuminator fabricated according to this embodiment is tested (loss of incident light is not considered for the convenience of experiment, the low-refractivity film 8 is not applied on the incident surface and reflection film 12 is not applied on the reflection surface). Instead, only a prefabricated reflection film is applied onto the reflection surface 7. A constant current 6 W power source is used and a test is conducted with a 1.5 m integrating sphere as follows:

| | | | Luminous |
|---|---|---|---|
| State of LED Surface Light | Luminous Flux | Brightness | Intensity |
| Source Illuminator | lm | mcd/m² | mcd |
| Emergence surface not covered | 163.89 | 66 | 96 |
| with a high-refractivity film | | | |
| Emergence surface covered with | 422.34 | 148 | 271 |
| a high-refractivity film | | | |
| Total luminous flux without an | 617.75 | 204 | 407.5 |
| illuminator | | | |

It is known from the test data that the luminous intensity with application of the high-refractivity film is increased by 1.82 times, the brightness is increased by 1.24 times, the luminous flux is increased by 1.58 times, the light guide efficiency of the illuminator is increased by more than 70% and the light guide efficiency is apparently increased. (As revealed by the Chinese invention patent No. CN100508222C, the light guide panel's efficiency is defined as the percentage of total effective luminous flux emitted from the main emergence surface of the light guide panel in total luminous flux coupled into the light guide panel. According to the data revealed by the technical document TP29 published by Lumileds Lighting in the US, the highest secondary efficiency of its large-power LED-based surface light source is 50% and the efficiency of light guide panel is about 60%.).

This embodiment adopts the nano titanium dioxide with a specific area greater than 140 m²/g and a particle size of 5 nm to 15 nm. The illuminator covered with the high-refractivity film 9 is an extremely good photocatalyst component and also has environment-friendly functions of air cleaning and sterilizing.

### Embodiment 2

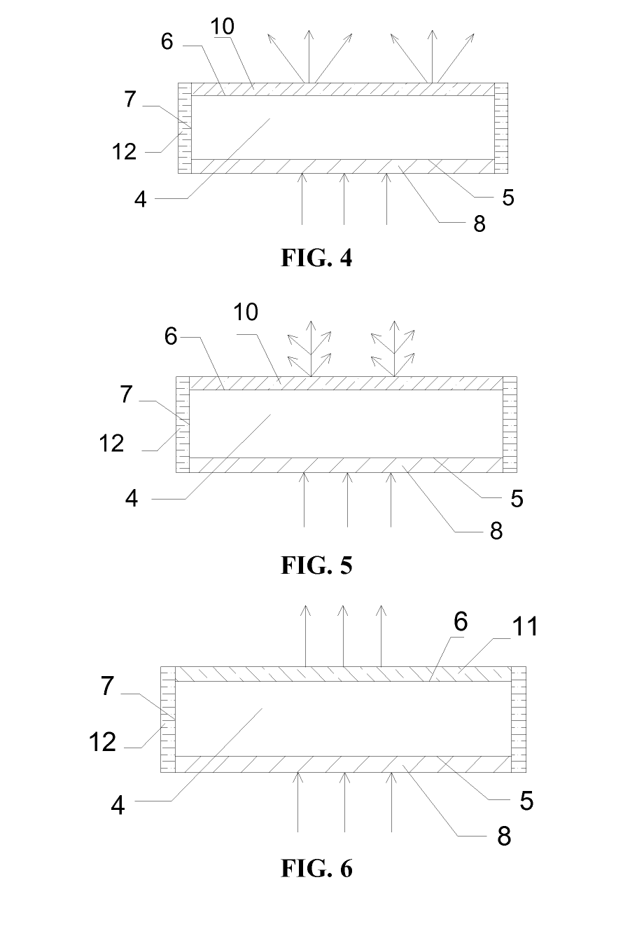

A multifunctional LED plane light source is provided. As shown in FIG. 3, the solid geometry 4 of the illuminator 2 is made of PMMA plate and its geometry is a solid polyhedron-a hexahedron and has totally six outer surfaces. It is an illuminator made of organic glass plate materials and its geometry is a solid polyhedron-hexahedron and has totally six outer surfaces. The LED point light source 1 illuminator is fixed unto one parallel surface of the hexahedron. This parallel surface is the incident surface 5 and another parallel surface is the emergence surface 6 (other side surfaces are reflection surfaces 7). It is a direct-entry illuminator with light incidence from one parallel surface of the geometry and light emergence from another parallel surface of the geometry. The emergence surface 6 is an emergence surface of a direct-entry illuminator and needs to be covered with a diffusion film 10. As shown in FIG. 4, this embodiment adopts high-purity silicon dioxide powder with a particle size greater than 0.78 μm and a refractivity of 1.61 as the diffusing agent, which is added to the transparent epoxy resin with a refractivity of 1.544. When the film thickness is 3 mm, the percentage of the added powder is 1% to 2%. After mixing and blending, it is applied onto the emergence surface of the direct-entry illuminator by collosol-gelatin method and cured into a solid dielectric think film. Since the diameter of the optical diffusing agent is larger than the wavelength of visible light (0.38 μm to 0.78 μm), the sufficient optical diffusing agent diffused in the resin can shield the light source effectively and a very small distance is present between two adjacent optical diffusion particles. Therefore, scattering is caused repeatedly so that the glaring incident light becomes gentle light to eyes and the effect of light transmitting but not transparent is achieved.

According to this embodiment, during actual fabrication, the incident surface is covered with a low-refractivity film 8 made of MgF₂(n₁=1.38), ZrO₂(n₂=2.1) and CeF₃(n₃=1.62), and the three-layer wideband antireflective film with the optical thickness controlled to 126 nm to 139 nm, 253 nm to 277 nm and 126 nm to 139 nm so that there is good antireflective effect with the entire spectrum of visible light. It further increases the utilization of LED point light source's emitted light and reduces the reflective loss of light wave most sensitive to the vision of human eyes at the incident surface.

During the actual fabrication of this embodiment, the reflection film 12 is a microprism, which effectively controls the angle of light emergence and achieves uniform light exit.

To improve the color temperature and color rendering index of surface light source, the emergence surface is covered with the diffusion film 10. As shown in FIG. 5, the LED point light source 1 uses an LED chip containing wavelength 365 nm to 410 nm for direct integration and binding to the line light source of the heat sink (not shown in the figure) to cover it with the diffusion film 10 or adds the fluorescent powder (the central particle size D50 is 8 μm to 20 μm) into the parent substance of the transparent epoxy resin. When the film thickness is 3 mm, the weight percent is 12% to 30%. After mixing and blending, it is applied to the emergence surface of the direct-entry illuminator and cured into the solid optical dielectric thick film. Since the fluorescent powder diffused in the resin can shield the light source effectively, a very smaller distance is present between two adjacent optical diffusion particles. Scattering is caused repeatedly and the fluorescent powder can be stimulated by using the fluorescent powder and the illumination efficiency can be improved, thereby improving the color temperature and rendering index of the surface light source, and turning the glaring incident light to gentle light.

To expand the functionality of the surface light source, the emergence surface of the surface light source is covered with a photocatalyst film 11. As shown in FIG. 6, nano titanium dioxide with a specific area of 50 to 250 m²/g and a particle size of 5 nm to 15 nm are added into parent substance of the transparent epoxy resin according to a weight percent of 0.1% to 3%, when the film thickness is 1 mm. After mixing and blending, the nano titanium dioxide is applied unto the emergence surface of direct-entry illuminator and cured into the solid optical dielectric thick film. The radiation containing light with a wavelength of 365 nm to 410 nm emitted from the emergence surface achieves the photocatalyst effect.

### Embodiment 3

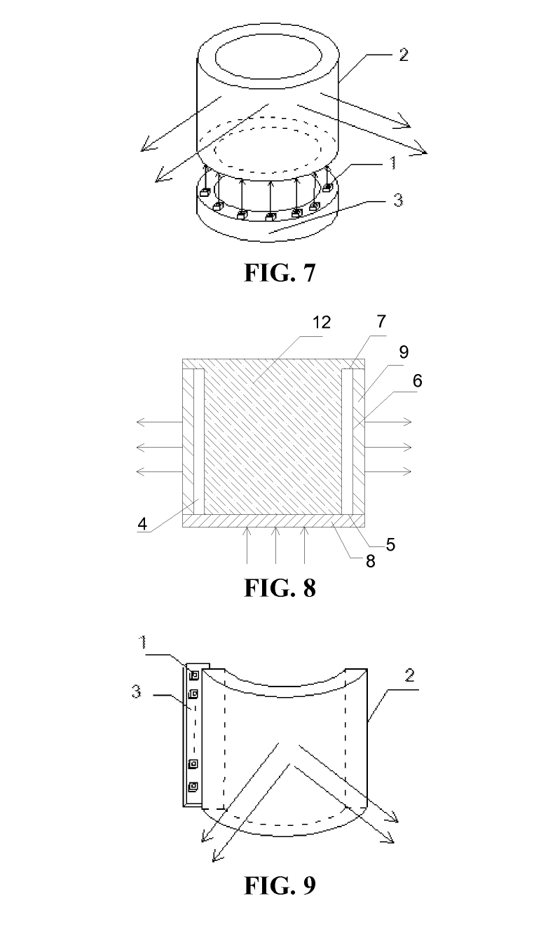

A tubular LED surface light source is provided. As shown in FIG. 7, the solid geometry of illuminator 2 is made of PMMA tubes and its geometry is a solid rotating body—circular geometry. The outer surface is comprised of two curved surfaces (inner surface and outer surface) and two bottom surfaces. The LED point light source 1 is arranged on one bottom surface of the circular geometry and the bottom surface is the incident surface 5. Therefore, FIG. 7 shows only one incident surface; the other bottom surface is the reflection surface 7 and the inner curved surface of the circular geometry is the reflection surface 7. The outer curved surface of the circular geometry is the emergence surface 6. The illuminator is a side-entry illuminator with light incidence from one bottom surface of the circular geometry and light emergence from the outer curved surface of the circular geometry. As shown in FIG. 8, the reflection surface 7 of this embodiment is covered with the reflection film 12, which is ZrO₂+SiO₂ multilayer reflection film series and the optical thickness of each film is respectively from an odd multiple of 126 nm to an odd multiple of 139 nm. The incident surface 5 is covered with the low-refractivity film 8 and the emergence surface 6 is covered with high-refractivity film 9. According to this embodiment, the low-refractivity film 8 and high-refractivity film 9 are applied, which are the same as in the above embodiment and thus are not detailed any further.

### Embodiment 4

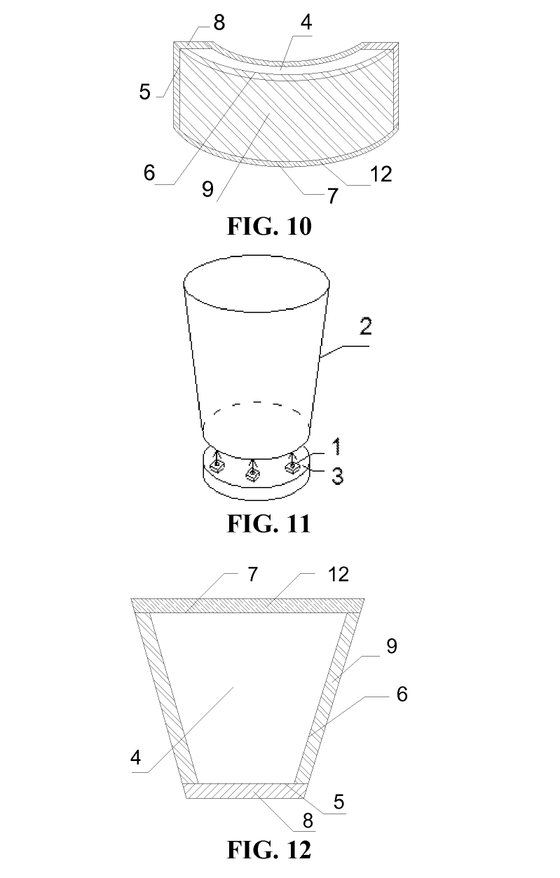

An LED curved-surface light source is provided. As shown in FIG. 9, the solid geometry of illuminator 2 is made of PMMA material and the geometry is a part of the rotating circular geometry and the outer surface is comprised of two planes, two curved surfaces and two circular surfaces. The LED point light source 1 is arranged on one side plane of the rotating circular geometry and the side plane is the incident surface 5. FIG. 9 shows only one incident surface. The outer curved surface of the circular geometry is the emergence surface 6 and other surfaces are all the reflection surfaces 7. The illuminator is a side-entry illuminator with light incidence from the side plane of the circular geometry and light exit from the outer side curved surface. As shown in FIG. 10, according to this embodiment, the reflection surface is covered with the reflection film 12, made of ZnS+MgF₂ or ZrO₂+SiO₂. The optical thickness of each layer is λ/4 (λ is from 507 nm to 555 nm) dielectric multilayer film with alternate arrangement of (507 nm to 555 nm)/4 (126.75 nm to 138.75 nm) high refractivity and low refractivity. The incident surface is covered with the low-refractivity film 8 and the emergence surface is covered with the high-refractivity film 9. In this embodiment, the low-refractivity film 8 and the high-refractivity film 9 are covered on the incident surface and the emergence surface, which are same as the above embodiment and are not detailed here again.

### Embodiment 5

A multifunctional LED columnar surface light source is provided. As shown in FIG. 11, the solid geometry of illuminator 2 is made of PMMA plates. The geometry is a solid rotating body—truncated cone geometry and the outer surface is made up of top surface, bottom surface and one side surface. This embodiment has many variations based on different usages:

1). As shown in FIG. 12, the LED point light source 1 is arranged on the bottom surface of the truncated bone and the bottom surface is the incident surface 5. Therefore, FIG. 12 shows only one incident surface. The truncated cone's top surface is the incident surface 7 and the side surface is the emergence surface 6. The illuminator is a side-entry illuminator with light incidence from bottom surface of the geometry and light emergence from the side surface thereof. The incident surface is covered with the low-refractivity film 8, the emergence surface is covered with the high-refractivity film 9 and the reflection surface is covered with the reflection film 12.

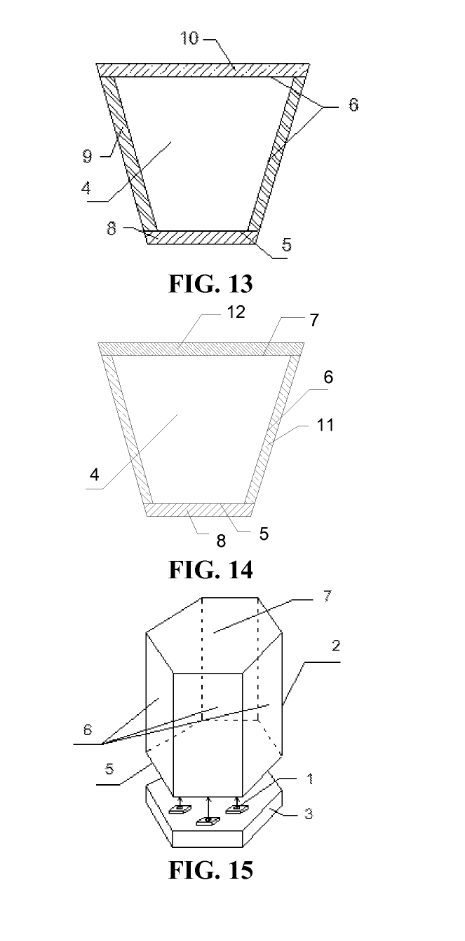

2). As shown in FIG. 13, the LED point light source 1 is arranged at the bottom surface of the truncated cone. The bottom surface is the incident surface 5 and the side and top surfaces are emergence surfaces 6. No reflection surface is provided. The illuminator is a mixed (side-entry and direct-entry) illuminator with light incidence from the bottom surface of the geometry and light emergence from the side surface and top surface. In this embodiment, the incident surface is covered with the low-refractivity film 8, one emergence surface, i.e., the side surface, is covered with the high-refractivity film 9 and another emergence surface, i.e., the top surface, is covered with the diffusion film 10.

3). As shown in FIG. 14, the solid geometry (4) is fabricated by special structures of the light guide plate by means of light guide technologies, such as mechanical engraving, printing dots and laser engraving (not shown in FIG. 14). The LED point light source 1 is an LED chip containing a wavelength of 365 nm to 410 nm, which is arranged on the bottom surface of the truncated bone. This bottom is the incident surface 5. Therefore, FIG. 14 shows only one incident surface. The top surface of the truncated cone is the incident surface 7 and the side surface thereof is the emergence surface 6. The illuminator is a side-entry illuminator with light incidence from the bottom surface of the geometry and light emergence from the side surface thereof. The incident surface is covered with the low-refractivity film 8 and the reflection surface is covered with the reflection film 12. According to this embodiment, the low-refractivity film 8, photocatalyst film 11 and reflection film 12 are applied, which are same with the above embodiment and are not be detailed any further.

### Embodiment 6

An LED polyhedron surface light source is provided. As shown in FIG. 15, the solid geometry of illuminator 2 is made of PMMA plates and its geometry is a solid polyhedron-hexagonal prism. The outer surface is comprised of the top, bottom and six side surfaces. The LED point light source 1 is arranged on the bottom surface of the hexagonal prism and the bottom surface is the incident surface 5. Therefore, FIG. 15 shows only one incident surface, the top surface is the reflection surface 7 and other six side surfaces are emergence surfaces. The illuminator is a side-entry illuminator with light incidence from the bottom surface of the geometry and light emergence from the side surface. In this embodiment, the incident surface is covered with the low-refractivity film 8, the emergence surface is covered with the high-refractivity film 9 and the reflection surface is covered with the reflection film 12. Optionally, the LED point light source 1 is arranged on one bottom surface of the prism and the bottom surface is the incident surface 5. Another bottom surface and other six side surfaces are emergence surfaces 6 and no reflection surface is provided. The illuminator is a mixed (side-entry and direct-entry) illuminator with light incidence from one bottom surface of the geometry and light emergence from other side surfaces and the other bottom surface. According to this embodiment, the low-refractivity film 8, high-refractivity film 9, diffusion film 10 and reflection film 12 are applied, which are same as in the above embodiment and are not detailed any further.

### Embodiment 7

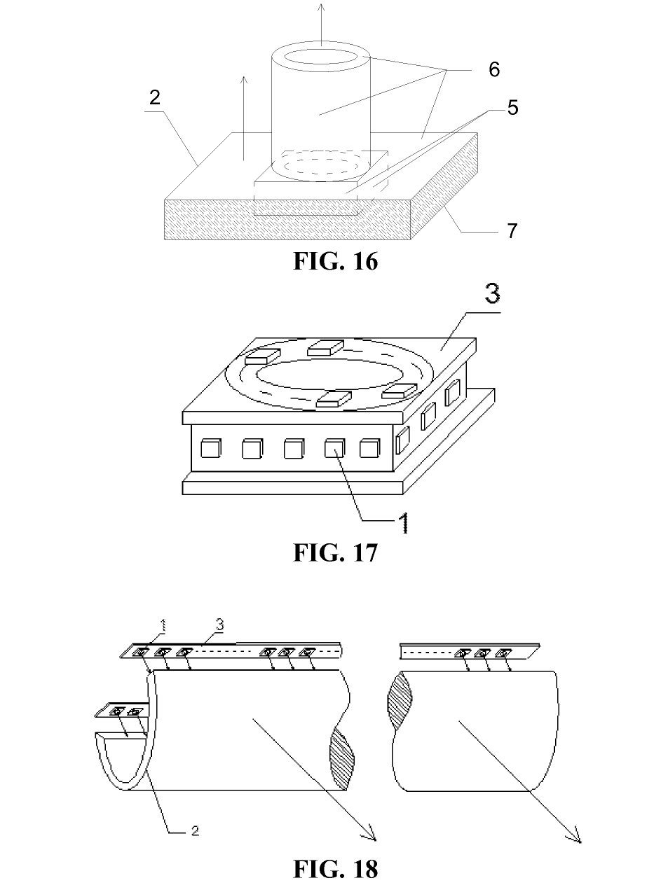

A special-shaped surface light source is provided. As shown in FIG. 16, the solid geometry of illuminator 2 is an assembly made of PMMA materials. The geometry is a combination of a solid rotating circular geometry and a solid rectangle, and the outer surface is comprised of ten planes, two curved surfaces (inner surface and outer surface) and two circular surfaces (top surface and bottom surface). As shown in FIG. 17, the LED point light source 1 is a prefabricated LED point light source module and an LED chip is directly bound to the light source module of the heat sink 3. During implementation, the light source module is directly embedded into four inner side surfaces and one lower circular surface of the assembly. Such four inner side planes and one lower circular surface are the incident surfaces 5. Therefore, FIG. 16 shows totally five incident surfaces. One outer curved surface, one top circular surface and one top plane of the assembly are all emergence surfaces 6. Other surfaces are the reflection surfaces 7. The illuminator is a mixed (side-entry and direct-entry) illuminator with light incidence from four inner side surfaces and one bottom circular surface of the geometry and light emergence from the upper circular surface, outer curved surface and top plane. In this embodiment, the incident surface is covered with the low-refractivity film 8, the emergence surface on the top plane and outer curved surface is covered with the high refractivity film 9, the emergence surface on the circular surface is covered with the diffusion layer 10 and the reflection surface is covered with the reflection film 12. According to this embodiment, the low-refractivity film 8, high-refractivity film 9, diffusion film 10 and reflection film 12 are applied, which are same as in the above embodiment and are not detailed any further.

### Embodiment 8

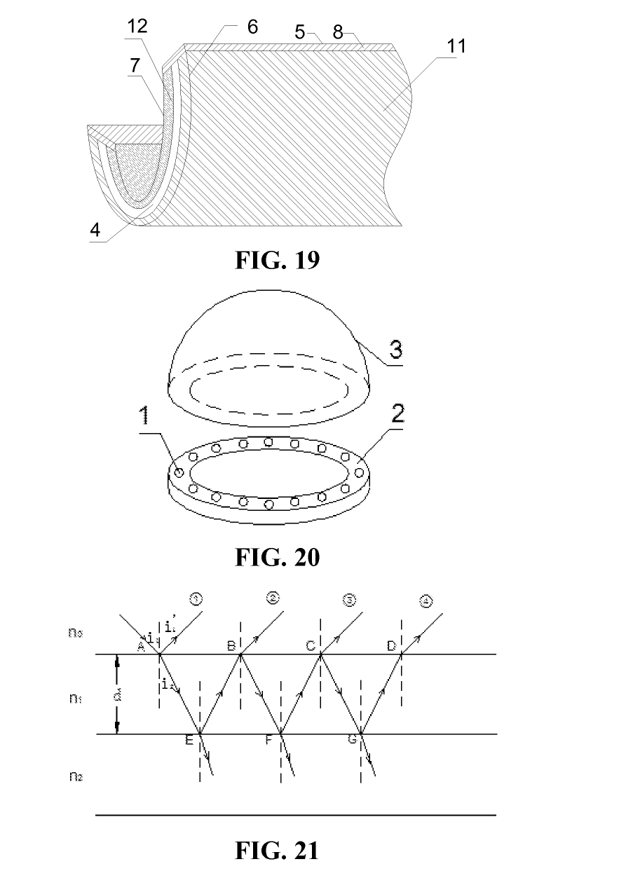

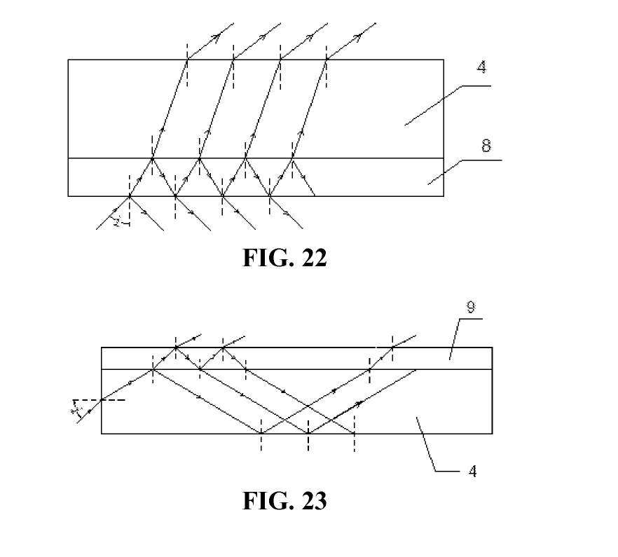

LED surface light source fluorescent lamp is provided. As shown in FIG. 18, the solid geometry of illuminator 2 is made of PMMA materials. The geometry is a part of the solid rotating circular geometry and the outer surface is comprised of two planes, two curved surfaces and two circular surfaces. The illuminator is a side-entry illuminator with light incidence from two side surfaces of the circular geometry and light emergence from one outer curved surface thereof. The LED point light source 1 is a prefabricated LED point light source module and an LED chip is directly bound to the light source module of the heat sink 3. During implementation, the light source module is directly arranged on side surfaces of the rotating circular geometry. FIG. 18 shows only two incident surfaces 5. The outer curved surface of circular geometry is the emergence surface 6, and the inner curved surface and other surfaces are the reflection surfaces 7. As shown in FIG. 19, in this embodiment, the incident surface is covered with the low-refractivity film 9, the emergence surface is covered with the high-refractivity film 9 or the photocatalyst film 11, and the reflection surface is covered with the reflection film 12. According to this embodiment, the optical films applied are same as in the above embodiment and are not detailed any further.

### Embodiment 9

An LED photocatalyst spherical lamp is provided. The LED point light source 1 is an LED photocatalyst spherical lamp with a spherical illuminator cover. As shown in FIG. 20, an LED chip containing a wavelength of 365 nm to 415 nm is directly bound to a prefabricated LED point light source module on the circular plane of the heat sink 3. The solid geometry 4 of the illuminator 2 is the optical glass or ceramic cover. The geometry is a solid polyhedron-a part of rotating spherical geometry. The thickness of the illuminator cover is greater than 3 mm and the illuminator's outer surface is comprised of two half spherical surfaces (inner surface and outer surface) and one circular plane. The LED point light source 1 is arranged at the circular plane of the geometry. This circular plane is the incident surface 5. Therefore, FIG. 20 shows only one incident surface. One inner half spherical surface is the reflection surface 7 and one outer half spherical surface is the emergence surface 6. During implementation, the light source module is arranged as light incidence from the circular plane and light emergence from the outer half spherical surface. The incident surface is covered with the photocatalyst film 11 by applying the organic chemical solution of nano titanium dioxide with an average particle size of 5 nm to 15 nm and a specific area (outer surface) greater than 140 m²/g onto the emergence surface 6 on the outer half spherical surface by means of application, film formation, drying and other processes. The film's optical thickness is controlled to an odd multiple of 91.25 nm to an odd multiple of 102.5 nm. In this embodiment, the incident surface is covered with the low-refractivity film 8 and the reflection surface is covered with the reflection film 12. The optical film according to this embodiment is same as that in above embodiments and is not detailed any further. As for the LED photocatalyst plane lamp and the LED photocatalyst curved surface lamp, only the geometry of the illuminator 2 is different, which is not detailed any further.

The practice-based experiments of lighting device in this embodiment show that pollution can be greatly reduced, the influence of pollution on luminous flux is mitigated, the cleaning frequency and the maintenance cost are reduced. In addition, it is further determined that that indoor lighting devices coated with photocatalyst achieves the effect of removing odor, with a most attractive function being its sterilizing effect. While killing bacteria, the photocatalyst also decomposes the toxin, which is a unique function of the photocatalyst. In view of its excellent antibacterial and dustproof photocatalyst reaction, the LED surface light source in the present invention gains a wide application. It is tested that, as for the illuminator covered with the photocatalyst optical film, hardness after drying is greater than and equal to 5H and the following cleaning effects are achieved: the concentration of toluene is decreased by 80%, ammonia's degradation rate is greater than and equal to 80%, formaldehyde's degradation rate is greater than and equal to 80%, hydrogen sulfide is greater than and equal to 90% and sterilization rate is greater than 98%. This embodiment illustrates an extremely good photocatalyst component, which can purify air and sterilize, and the illuminator illustrated in this embodiment is an extremely good environment-friendly illuminator.

After the present invention is covered by the optical film, it not only overcomes direct glaring caused by LED point light source, but also produces directly an optical film on the outer surface o the illuminator's solid geometry. This greatly improves the luminous intensity of surface light source and propagates its functions to air cleaning sterilizing, antistatic, optical medical care and plant illumination in addition to the functions as a lighting device, display light and backlight source. It can be fabricated to an LED purifying lighting device, an LED sterilizing lighting device, an LED antistatic lighting device, an LED optical medication lighting device and an LED plant illumination device. Along with the development of electronic thin film technologies, more business opportunities will be brought for the application of LED surface light source.

It should be noted that above embodiments are merely exemplary ones of the present invention. Obviously, the present invention is not limited to above embodiments, but has many variations. All variations that a person skilled in the art derives from or directly reaches form the contents disclosed in the present invention shall be considered as falling into the protective scope of the present invention.

What is claimed is:

1. An illuminating device with an LED surface light source covered with an optical film, comprising an LED point light source (1), an illuminator (2), and a heat sink (3), wherein:
the illuminator (2) is an optically transparent solid geometry (4) with an optical film covering the outer surface thereof;
wherein at least one outer surface of the solid geometry (4) is an incident surface (5) and at least one outer surface of the solid geometry is an emergence surface (6);
the outer surface of the solid geometry (4) of the solid geometry the illuminator (2) is provided with at least one optical dielectric film made of submicron particles or nano particles, the thickness of the film being from 91 nm to 5 mm; and
the LED point light source (1) is fixed on the heat sink (3), matching with the incident surface (5) of the illuminator (2).

2. The illuminating device with an LED surface light source covered with an optical film according to claim 1, wherein: the optical film is a thick film with a thickness of 0.01 mm to 5 mm, wherein the thick film is a solid optical dielectric thick film of an polymer prepared by diffusing nano titanium dioxide with an average particle size of 5 nm to 100 nm or silicon dioxide or light barium sulfate with particle size greater than 0.78 μm, into parent substance of optically transparent epoxy resin or optically transparent silicon resin.

3. The illuminating device with an LED surface light source covered with an optical film according to claim 1, wherein the optical film is a functional optical dielectric thin film made of at least one layer of optical dielectric material, the optical thickness of the film being from an odd multiple of 91 nm to an odd multiple of 195 nm.

4. The illuminating device with an LED surface light source covered with an optical film according to claim 1, wherein: the LED point light source comprises an LED chip having a wavelength of 365 nm to 410 nm; the emergence surface of the solid geometry (4) is covered with a photocatalyst film (11); wherein the photocatalyst film (11) is a solid optical dielectric thick film of an polymer prepared by diffusing nano titanium dioxide with an average particle size of 5 nm to 15 nm and a specific outer surface area greater than 140 m²/g, into parent substance of epoxy resin or silicon resin according to a weight percent of 0.1% to 10%, the thickness of the film being from 0.1 mm to 3 mm; or is a functional optical dielectric thin film made of nano titanium dioxide with an average particle size of 5 nm to 15 nm and a specific outer surface area greater than 140 m²/g, the thickness of the film being from an odd multiple of 91.25 nm to an odd multiple of 102.5 nm.

5. The illuminating device with an LED surface light source covered with an optical film according to claim 1, wherein: the emergence surface of the side-entry illuminator of the solid geometry (4) is covered a high-refractivity film (9); wherein the high-refractivity film (9) is a solid optical dielectric thick film of a polymer prepared by diffusing nano titanium dioxide with an average particle size of 5 nm to 15 nm and a specific area of 50 m²/g to 250 m²/g, into parent substance of optically transparent epoxy resin or optically transparent silicon resin according to a weight percent of 0.1% to 0.5%, the thickness of the film being from 0.01 mm to 1 mm, the light transmission rate being greater than 90%, and the light guide efficiency being greater than 70%; or is a functional optical dielectric thin film with a refractivity greater than that of the solid geometry, an optical thickness of an odd multiple of 126 nm to an odd multiple of 139 nm, a light transmission rate greater than 90%, and a light guide efficiency of the emergence surface greater than 70%; or is a nano titanium optical film with a specific area of 50 m²/g to 250 m²/g, an average particle size of 5 nm to 15 nm, an optical thickness of an odd multiple 126 nm to an odd multiple of 139 nm, a light transmission rate greater than 90%, and a light guide efficiency of the emergence surface greater than 70%.

6. The illuminating device with an LED surface light source covered with an optical film according to claim 1, wherein: the emergence surface of the direct-entry illuminator of the solid geometry (4) is covered with a diffusion film (10); wherein the diffusion film (10) is a solid optical dielectric thick film of a polymer prepared by diffusing optical diffusing agent into parent substance of optically transparent epoxy resin or optically transparent silicon resin according to a weight percent of 0.1% to 5%, the thickness of the film being from 1 mm to 5 mm, the haze being greater than 80%, the diffusion rate being greater than 0.6, and the light guide efficiency being greater than 80%; or is a solid optical dielectric thick film of a polymer prepared by diffusing fluorescent powder into parent substance of optically transparent epoxy resin or optically transparent silicon resin according to a weight percent of 5% to 30%, the thickness of the film being from 0.1 mm to 3 mm and the central particle size D50 of the fluorescent powder being from 8 μm to 20 μm; or is a solid optical dielectric thick film of a polymer prepared by diffusing silicon dioxide or light barium sulfate with particle size greater than 0.78 μm into parent substance of optically transparent epoxy resin or optically transparent silicon resin according to a weight percent of 1% to 5%, the thickness of the film being from 1 mm to 3 mm.

7. The illuminating device with an LED surface light source covered with an optical film according to claim 1, wherein: the incident surface (5) is covered with a low-refractivity film (8); wherein the low-refractivity film (8) is an incident film with a refractivity smaller than that of the solid geometry and an optical thickness of an odd multiple of 126 nm to an odd multiple of 139 nm; or is a three-layer wideband antireflective film made of MgF₂, ZrO₂, and CeF₃, with optical thicknesses of 126 nm to 139 nm, 253 nm to 277 nm, and 126 nm to 139 nm respectively.

8. The illuminating device with an LED surface light source covered with an optical film according to claim 1, wherein: a reflection surface (7) of the solid geometry (4) is covered with a reflection film (12); wherein the reflection film (12) is a multi-layer reflection film made of ZrO₂ and SiO₂, the optical thickness of each film being from an odd multiple of 126 nm to an odd multiple of 139 nm; or is a dielectric multilayer reflection film with low refractivity and high refractivity alternated, the optical thickness of each film being from 126 nm to 139 nm; or is a prism reflection film; or is a reflection film embedded inside the reflection surface (7) and having a reflectivity greater than 90%; or is a reflection film adhered on the reflection surface (7) and having a reflectivity greater than 90%.

9. The illuminating device with an LED surface light source covered with an optical film according to claim 1, wherein the solid geometry (4) is a solid polyhedron, a solid rotating body, or a special-shaped solid geometry integrated thereby.

10. The illuminating device with an LED surface light source covered with an optical film according to claim 1, wherein the LED point light source (1) is a pre-fabricated light source module or an LED line light source or extended light source with an LED chip integrated on the heat sink.

11. A method for fabricating an illuminating device with an LED surface light source covered by an optical film, comprising fabrication of an illuminator, arrangement of an optical film, coverage and fabrication of an optical film, and fabrication of a light source; wherein the specific operation process comprise the following steps:
selecting a qualified material to fabricate through common manufacturing into a transparent solid geometry (4), wherein at least one outer surface of the solid geometry (4) is an incident surface (5) and at least one outer face of the solid geometry is an emergence surface (6);
categorizing point light sources (1) into side-entry illuminators and direct-entry illuminators according to different arrangement positions of the point light sources (1) of the fabricated solid geometry; wherein the side-entry illuminator is an illuminator transmitting incident light using light full reflection but emitting light from the emergence surface by undermining the full reflection condition, and the direct-entry illuminator is an illuminator transmitting the incident light along a straight line but emitting scattering light deviating from the incident direction;
arranging different optical films according to different emergence surfaces (6); wherein: the emergence surface (6) of the side-entry illuminator is provided with a high-refractivity film (9), wherein the high-refractivity film is prepared by diffusing nano titanium dioxide with an average particle size of 5 nm to 15 nm and a specific area of 50 m²/g to 250 m²/g into parent substance of optically transparent epoxy resin or optically transparent silicon resin according to a weight percent of 0.1% to 0.5% to form a polymer and by stirring to mix the polymer; the emergence surface (6) of the direct-entry illuminator is provided with a diffusion film (10), wherein the diffusion film (10) is a prepared by diffusing silicon dioxide or light barium sulfate with particle size greater than 0.78 μm into parent substance of optically transparent epoxy resin or optically transparent silicon resin according to a weight percent of 1% to 5% to form a polymer and by stirring to mix the polymer;
coating the prepared optical film polymer on the emergence surface (6) for solidification by using a common film fabrication method, to form a solid optical dielectric thick film, wherein the solidification temperature is lower than 60° C., and covering the other outer surfaces of the solid geometry (4) during the coating; and
selecting requirement-compliant LED points sources (1), soldering the light sources on a qualified aluminum-based printed circuit board, fixing the light sources on heat sinks (3), and arranging the light sources on an incident surface (5) of the illuminator (2).

12. The method for fabricating an illuminating device with an LED surface light source covered by an optical film according to claim 11, wherein: the outer surface of the solid geometry (4) of the solid geometry the illuminator (2) is provided with at least one optical dielectric film made of submicron particles or nano particles, the thickness of the film being from 91 nm to 5 mm; the optical film is a thick film with a thickness of 0.01 mm to 5 mm, wherein the thick film is a solid optical dielectric thick film of an polymer prepared by diffusing nano titanium dioxide with an average particle size of 5 nm to 100 nm or silicon dioxide or light barium sulfate with particle size greater than 0.78 μm, into parent substance of optically transparent epoxy resin or optically transparent silicon resin.

13. The method for fabricating an illuminating device with an LED surface light source covered by an optical film according to claim 11, wherein the optical film is a functional optical dielectric thin film made of at least one layer of optical dielectric material, the optical thickness of the film being from an odd multiple of 91 nm to an odd multiple of 195 nm.

14. The method for fabricating illuminating device with an LED surface light source covered with an optical film according to claim 11, wherein: the LED point light source comprises an LED chip having a wavelength of 365 nm to 410 nm; the emergence surface of the solid geometry (4) is covered with a photocatalyst film (11); wherein the photocatalyst film (11) is a solid optical dielectric thick film of an polymer prepared by diffusing nano titanium dioxide with an average particle size of 5 nm to 15 nm and a specific outer surface area greater than 2 m²/g, into parent substance of epoxy resin or silicon resin, the thickness of the film being 0.1 mm to 3 mm; or is a functional optical dielectric thin film made of nano titanium dioxide with an average particle size of 5 nm to 15 nm and a specific outer surface area greater than 140 m²/g, the thickness of the film being from an odd multiple of 91.25 nm to an odd multiple of 102.5 nm.

15. The method for fabricating an illuminating device with an LED surface light source covered with an optical film according to claim 11, wherein: the emergence surface of the side-entry illuminator of the solid geometry (4) is covered a high-refractivity film (9); wherein the high-refractivity film (9) is a solid optical dielectric thick film of a polymer prepared by diffusing nano titanium dioxide with an average particle size of 5 nm to 15 nm and a specific area of 2 m²/g to 2 m²/g, into parent substance of optically transparent epoxy resin or optically transparent silicon resin according to a weight percent of 0.1% to 0.5%, the thickness of the film being from 0.01 mm to 0.05 mm, the light transmission rate being greater than 90%, and the light guide efficiency being greater than 70%; or is a functional optical dielectric thin film with a refractivity greater than that of the solid geometry, an optical thickness of an odd multiple of 126 nm to an odd multiple of 139 nm, and a light guide efficiency of the emergence surface greater than 70%; or is a nano titanium optical film with a specific area of 2 m²/g to 2 m²/g, an average particle size of 5 nm to 15 nm, an optical thickness of an odd multiple 126 nm to an odd multiple of 139 nm, and a light guide efficiency of the emergence surface greater than 70%.

16. The method for fabricating an illuminating device with an LED surface light source covered with an optical film according to claim 11, wherein: the emergence surface of the direct-entry illuminator of the solid geometry (4) is covered with a diffusion film (10); wherein the diffusion film (10) is a solid optical dielectric thick film of a polymer prepared by diffusing optical diffusing agent into parent substance of optically transparent epoxy resin or optically transparent silicon resin according to a weight percent of 0.1% to 5%, the thickness of the film being from 1 mm to 5 mm, the haze being greater than 80%, the diffusion rate being greater than 0.6, and the light guide efficiency being greater than 80%; or is a solid optical dielectric thick film of a polymer prepared by diffusing fluorescent powder into parent substance of optically transparent epoxy resin or optically transparent silicon resin according to a weight percent of 5% to 30%, the thickness of the film being from 0.1 mm to 3 mm and the central particle size of the fluorescent powder being from 8 μm to 20 μm; or is a solid optical dielectric thick film of a polymer prepared by diffusing silicon dioxide or light barium sulfate with particle size greater than 0.78 μm into parent substance of optically transparent epoxy resin or optically transparent silicon resin, the thickness of the film being from 1 mm to 3 mm.

17. The method for fabricating an illuminating device with an LED surface light source covered with an optical film according to claim 11, wherein: the incident surface (5) is covered with a low-refractivity film (8); wherein the low-refractivity film (8) is an incident film with a refractivity smaller than that of the solid geometry and an optical thickness of an odd multiple of 126 nm to an odd multiple of 139 nm; or is a three-layer wideband antireflective film made of MgF₂, ZrO₂, and CeF₃, with optical thicknesses of 126 nm to 139 nm, 253 nm to 277 nm, and 126 nm to 139 nm respectively.

18. The method for fabricating an illuminating device with an LED surface light source covered with an optical film according to claim 11, wherein: a reflection surface (7) of the solid geometry (4) is covered with a reflection film (12); wherein the reflection film (12) is a multi-layer reflection film made of ZrO₂ and SiO₂, the optical thickness of each film being from an odd multiple of 126 nm to an odd multiple of 139 nm; or is a dielectric multilayer reflection film with low refractivity alternated, the optical thickness of each film being from 126 nm to 139 nm; or is a reflection film embedded inside the reflection surface (7) and having a reflectivity greater than 90%; or is a reflection film adhered on the reflection surface (7) and having a reflectivity greater than 90%.

19. The method for fabricating an illuminating device with an LED surface light source covered with an optical film according to claim 11, wherein the solid geometry (4) is a solid polyhedron, a solid rotating body, or a special-shaped solid geometry integrated thereby.

20. The method for fabricating an illuminating device with an LED surface light source covered with an optical film according to claim 11, wherein the LED point light source (1) is a pre-fabricated light source module or an LED line light source or extended light source with an LED chip integrated on the heat sink.
